(19) United States
(12) Patent Application Publication
(10) Pub. No.: US 2026/0226605 A1
(43) Pub. Date: Aug. 6, 2026

(54) OXIDE SPUTTERING TARGET AND OXIDE FILM

(71) Applicant: JX ADVANCED METALS CORPORATION, TOKYO (JP)

(72) Inventors: Kei MUNEYASU, Ibaraki (JP); Atsushi NARA, Ibaraki (JP); Daiki OTOMO, Ibaraki (JP)

(21) Appl. No.: 19/149,655

(22) PCT Filed: Jan. 22, 2024
(86) PCT No.: PCT/JP2024/001584

§ 371 Date: Jul. 21, 2025

(30) Foreign Application Priority Data
Mar. 29, 2023 (JP) 2023-053278

(51) Int. Cl. C23C 14/34; C23C 14/08

(52) U.S. Cl. CPC C23C 14/3414; C23C 14/083

(57) ABSTRACT

An object of the present invention is to provide an oxide film having favorable etching processability and excellent weatherability (small rate of change of transmittance), and having a light absorption ability suitable for preventing the reflection of light. The oxide film contains molybdenum (Mo), niobium (Nb), zinc (Zn), and oxygen (O), wherein an etching rate is 1 nm/sec or higher, a rate of change of an average transmittance of a visible light region (wavelength: 400 to 700 nm) before and after a constant-temperature, constant-humidity test is within 15%, and an average reflectance against incident light in a visible light region (wavelength: 400 to 700 nm) is 15% or less.

### TECHNICAL FIELD

The present invention relates to an oxide sputtering target and an oxide film.

### BACKGROUND ART

Transparent conductive films made from ITO (indium tin oxide) are being used as wiring materials in liquid crystal displays, plasma displays, organic EL displays, touch panels, solar cells, and the like. ITO films exhibit superior transparency to visible light and have low resistivity among oxides, making them excellent materials for use as wiring materials. Nevertheless, when displays and panels are enlarged, resistance increases, and there is a problem in that ITO films cannot be used in enlarged displays and panels.

Such being the case, the use of metal films having low resistivity as wiring materials in place of ITO films is being considered. Nevertheless, when a metal film is used as a wiring material, there is a problem in that the metal film would reflect visible light, and cause deterioration in the visibility of displays and panels. To deal with this problem, attempts have been made to improve visibility by forming a film (also referred to as a black matrix) capable of absorbing reflected light near the metal film and thereby suppressing the reflection of light caused by the metal film.

In relation to a film for reducing the reflection of light, the present applicant has previously proposed a technology concerning an oxide thin film of Nb, Mo, and O (oxygen) having a light absorption ability suitable for preventing the reflection of light (Patent Document 1). This oxide thin film is a light absorbing film having favorable etching processability and excellent weatherability. Moreover, Patent Document 2 discloses a technology concerning a sputtering target for manufacturing a light absorbing layer from a target material containing an oxide phase and having an oxygen content that is lower than the stoichiometric composition.

### PRIOR ART DOCUMENTS

### Patent Documents

[Patent Document 1] International Publication No. 2019/176552
[Patent Document 2] Japanese Translation of PCT International Application Publication No. 2019-529705

### SUMMARY OF THE INVENTION

### Problems to be Solved by the Invention

An object of the present invention is to provide an oxide film having favorable etching processability and excellent weatherability (small rate of change of transmittance), and having a light absorption ability suitable for preventing the reflection of light, and an oxide sputtering target suitable for depositing such an oxide film.

### Means for Solving the Problems

The oxide sputtering target of the present disclosure contains molybdenum (Mo), niobium (Nb), zinc (Zn), and oxygen (O), wherein the oxide sputtering target includes a Zn₂Mo₃O₈ phase and/or a Zn₃Mo₃O₈ phase, and a content ratio of the Zn, in terms of atomic ratio, is 0.13≤Zn/(Mo+Nb+Zn)≤0.50.

The oxide film of the present disclosure contains molybdenum (Mo), niobium (Nb), zinc (Zn), and oxygen (O), wherein an etching rate is 1 nm/sec or higher, an average reflectance against incident light in a visible light region (wavelength: 400 to 700 nm) is 15% or less, and a rate of change of an average transmittance in a visible light region (wavelength: 400 to 700 nm) before and after a constant-temperature, constant-humidity test is within 15%.

### Effect of the Invention

According to the present invention, it is possible to obtain an oxide film having favorable etching processability and excellent weatherability (small rate of change of transmittance), and having a light absorption ability suitable for preventing the reflection of light. Moreover, according to the present invention, it is possible to obtain an oxide sputtering target suitable for forming the oxide film.

### BEST MODE FOR CARRYING OUT THE INVENTION

The use of metal films made of metals such as copper and aluminum, which have low resistivity, as wiring materials for various displays, touch panels, solar cells, and the like is being considered. Nevertheless, when a metal film is used as a wiring material, there is a problem in that the metal film would reflect visible light, and cause deterioration in the visibility of displays and panels. To deal with this problem, attempts have been made to improve visibility by forming a film (anti-reflection film) capable of absorbing reflected light near the metal film and thereby suppressing the reflection of light caused by the metal film.

Using a metal film as an anti-reflection film can be considered. Nevertheless, in this case, while a metal film exhibits superior light absorption ability, metal reflection unique to metals will occur, and it is difficult to reduce this metal reflection. While it is also possible to consider adopting a two-layer structure by forming an oxide film on the metal film as the anti-reflection film, this will result in an increase in the number of manufacturing processes and the deterioration in the production efficiency. Meanwhile, it is also possible to consider using a single oxide film as the anti-reflection film. In this case, while the surface reflection can be suppressed as metal reflection will not occur, because the light absorption ability is inferior in comparison to a metal film, the transmittance is high, and reflected light from the wiring material such as the lower electrode becomes noticeable, and this may deteriorate the visibility.

In this regard, among the single oxide films, NbO₂ and MoO₂ are materials with relatively low transmittance of visible light and low reflectance, and are considered to be useful as an anti-reflection film. Nevertheless, in the case of a NbO₂ film (single), while its deterioration with age is small and it exhibits superior weatherability, it is difficult to dissolve in etching solutions other than hydrogen fluoride (HF), and there is a problem in that processing by etching is difficult. In particular, there is a problem in that it is difficult to perform simultaneous etching with a metal film, which is a wiring material. Moreover, in the case of a MoO₂ film (single), the etching rate is fast and etching is possible under the same conditions as a metal film, but the weatherability will deteriorate. Accordingly, there is a trade-off between the etching rate and the weatherability.

As a result of intense study, the present inventors and others have discovered that an oxide film containing molybdenum (Mo), niobium (Nb), zinc (Zn), and oxygen (O), in which the content ratio of each metal component is appropriately adjusted, exhibits favorable etching processability (simultaneous etching with a metal film is possible) and excellent weatherability (small rate of change of transmittance), has a light absorption ability suitable for preventing the reflection of light, and functions effectively as an anti-reflection film.

An embodiment of the present invention is now explained in detail.

### [Oxide Film]

When the oxide film according to this embodiment, as a film having favorable etching processability, is etched under the following conditions, the etching rate is 1.0 nm/sec or higher. When the etching rate is 1.0 nm/sec or higher, etching can be performed under the same conditions as a metal film (at least copper). The etching rate is preferably 1.1 nm/sec or higher, more preferably 1.3 nm/sec or higher, and most preferably 1.4 nm/sec or higher.

### (Etching Conditions)

A hydrogen peroxide (H₂O₂)-based chemical liquid is used as the etching solution, the liquid temperature is set to 35° C., and an oxide film (sample) deposited on a substrate is immersed in the etching solution and etched for a predetermined period of time while agitating the etching solution. The sample is thereafter removed from the etching solution and the film thickness is measured. The etching rate is calculated from the time required for the etching (immersion time), and the reduction in the film thickness of the oxide film (=(film thickness before etching)−(film thickness after etching)).

With the oxide film according to this embodiment, as a film that exhibits excellent weatherability (small rate of change of transmittance), the rate of change of the average transmittance in the visible light region (wavelength: 400 to 700 nm) before and after a constant-temperature, constant-humidity test is within 14%, more preferably within 13%, and most preferably within 10%. The average transmittance is obtained by measuring the transmittance at 5 nm intervals in the wavelength region (400 to 700 nm), and calculating the average value thereof. The rate of change of transmittance is obtained by leaving a sample of the oxide film deposited on a glass substrate in a controlled room (atmosphere: air, temperature: 85° C., humidity: 85%) as a constant-temperature, constant-humidity test, measuring the transmittance of the sample after the lapse of 14 days, comparing the result with the measurement value of the transmittance before constant-temperature, constant-humidity test, and then checking the amount of change. In other words, the rate of change of transmittance is calculated from the following formula.

$$Rate of change of transmittance ( \% ) = \{ ( ( transmittance after constant - temperature , constant - humidity test ) - ( transmittance before constant - temperature , constant - humidity test ) \} / ( transmittance before constant - temperature , constant - humidity test ) \times 100$$

With the oxide film according to this embodiment, as a film that has a light absorption ability suitable for preventing the reflection of light, the average reflectance against incident light in the visible light region (wavelength: 400 to 700 nm) is 15% or less. The average reflectance is preferably 14% or less, more preferably 12% or less, and most preferably 10% or less. The average reflectance is obtained by measuring the reflectance at 5 nm intervals in the wavelength region (400 to 700 nm), and calculating the average value thereof. The reflectance is measured by depositing copper on a glass substrate and laminating an oxide film on the deposited copper to prepare a sample, and measuring the reflectance of light incident from the film side. Note that the reflected light includes specular reflected light and diffuse reflected light, but in the present disclosure, the reflectance will be the relative total light reflectance as the total reflectance of both specular reflected light and diffuse reflected light.

With the oxide film of this embodiment, the content ratio (atomic ratio) of Zn is preferably 0.13 or more in terms of Zn/(Mo+Nb+Zn). This is because when the content ratio of Zn increases, the etching rate of the oxide film will increase, and the weatherability will also improve. The content ratio of Zn is more preferably 0.15 or more, and most preferably 0.20 or more. Meanwhile, the content ratio (atomic ratio) of Zn is preferably 0.50 or less in terms of Zn/(Mo+Nb+Zn). This is because if the content ratio (atomic ratio) of Zn is excessively high, the light absorption ability of the oxide film will deteriorate considerably, and the reflectance will increase when the oxide film is laminated with a metal film.

With the oxide film of this embodiment, the content ratio (atomic ratio) of Mo is preferably 0.30 or more in terms of Mo/(Mo+Nb+Zn). This is because when the content ratio of Mo increases, the etching rate of the oxide film will increase. The content ratio of Mo is more preferably 0.33 or more, and most preferably 0.35 or more. Meanwhile, the content ratio (atomic ratio) of Mo is preferably 0.70 or less in terms of Mo/(Mo+Nb+Zn). This is because if the content ratio of Mo is excessively high, the weatherability of the oxide film will deteriorate considerably. The content ratio of Mo is more preferably 0.65 or less.

With the oxide film of this embodiment, the content ratio (atomic ratio) of Nb is preferably 0.15 or more in terms of Nb/(Mo+Nb+Zn). This is because when the content ratio of Nb increases, the weatherability will improve. The content ratio of Nb is more preferably 0.18 or more, and most preferably 0.20 or more. Meanwhile, the content ratio (atomic ratio) of Nb is preferably 0.30 or less in terms of Nb/(Mo+Nb+Zn). This is because if the content ratio of Nb is excessively high, the etching rate of the oxide film will deteriorate considerably. The content ratio of Nb is more preferably 0.28 or less, and most preferably 0.26 or less.

With the oxide film of this embodiment, the film thickness is preferably 15 nm or more and 1000 nm or less. When the film thickness is less than 15 nm, the light absorption ability may deteriorate. Meanwhile, when the film thickness exceeds 1000 nm, this is undesirable as it will take more time than necessary for the deposition process. Nevertheless, because the film thickness is ultimately determined by the device design, the film thickness is not limited to the foregoing range so as long as the light absorption ability is at least ensured. The film thickness is more preferably 30 nm or more and 500 nm or less.

The oxide film of this embodiment is preferably amorphous (non-crystalline). Compared to a crystallized film, an amorphous film has smaller film stress and is uniform, and therefore has the advantage of having fewer film defects. Due to this advantage, it is possible to reduce the probability of peeling or defects occurring when the oxide film is deposited on a flexible substrate. In the present disclosure, whether or not the oxide film is amorphous is determined, as described later, by analyzing the oxide film with the X-ray diffraction method and examining whether there is a diffraction peak in a predetermined range.

### [Oxide Sputtering Target]

The oxide sputtering target according to this embodiment contains molybdenum (Mo), niobium (Nb), zinc (Zn), and oxygen (O), includes a Zn₂Mo₃O₈ phase and/or a Zn₃Mo₃O₈ phase, and a content ratio (atomic ratio) of the Zn is 0.13≤Zn/(Mo+Nb+Zn)≤0.50. The oxide sputtering target according to this embodiment is useful for forming the oxide film according to this embodiment.

With the oxide sputtering target of this embodiment, the content ratio (atomic ratio) of Zn is 0.13 or more in terms of Zn/(Mo+Nb+Zn). This is because when the content ratio of Zn increases, the etching rate of the oxide film deposited using this sputtering target will increase, and the weatherability will also improve. The content ratio of Zn is more preferably 0.15 or more, and most preferably 0.20 or more. Meanwhile, with the oxide sputtering target of this embodiment, the content ratio (atomic ratio) of Zn is 0.50 or less in terms of Zn/(Mo+Nb+Zn). This is because if the content ratio (atomic ratio) of Zn is excessively high, the light absorption ability of the oxide film deposited using this sputtering target will deteriorate considerably, and the reflectance will increase when the oxide film is laminated with a metal film.

With the oxide sputtering target of this embodiment, the content ratio (atomic ratio) of Mo is preferably 0.30 or more in terms of Mo/(Mo+Nb+Zn). This is because when the content ratio of Mo increases, the etching rate of the oxide film deposited using this sputtering target will increase. The content ratio of Mo is more preferably 0.33 or more, and most preferably 0.35 or more. Meanwhile, the content ratio (atomic ratio) of Mo is preferably 0.70 or less in terms of Mo/(Mo+Nb+Zn). This is because if the content ratio of Mo is excessively high, the weatherability of the oxide film deposited using this sputtering target will deteriorate considerably. The content ratio of Mo is more preferably 0.65 or less.

With the oxide sputtering target of this embodiment, the content ratio (atomic ratio) of Nb is preferably 0.15 or more in terms of Nb/(Mo+Nb+Zn). This is because when the content ratio of Nb increases, the weatherability of the oxide film deposited using this puttering target will improve. The content ratio of Nb is more preferably 0.18 or more, and most preferably 0.20 or more. Meanwhile, the content ratio (atomic ratio) of Nb is preferably 0.30 or less in terms of Nb/(Mo+Nb+Zn). This is because if the content ratio of Nb is excessively high, the etching rate of the oxide film deposited using this sputtering target will deteriorate considerably. The content ratio of Nb is more preferably 0.28 or less, and most preferably 0.26 or less.

The oxide sputtering target according to this embodiment includes a Zn₂Mo₃O₈ phase and/or a Zn₃Mo₃O₈ phase. The Zn₂Mo₃O₈ phase and/or the Zn₃Mo₃O₈ phase has higher crystal stability than Mo oxide alone, and can be expected to improve the weatherability. The presence or absence of the Zn₂Mo₃O₈ phase and the Zn₃Mo₃O₈ phase can be confirmed by X-ray diffraction analysis (XRD).

In the present disclosure, it is determined that the Zn₂Mo₃O₈ phase is present when I₂/I₀, which is the ratio of the XRD peak intensity I₂ attributable to the (102) plane of the Zn₂Mo₃O₈ phase and the background intensity I₀, satisfies I₂/I₀>2. Moreover, it is determined that the Zn₃Mo₃O₈ phase is present when I₃/I₀, which is the ratio of the XRD peak intensity I₃ attributable to the (006) plane of the Zn₃Mo₃O₈ phase and the background intensity I₀, satisfies I₃/I₀>2.

The oxide sputtering target according to this embodiment preferably has a relative density of 90% or more. When the relative density is 90% or more, the generation of particles during sputtering can be suppressed. The relative density is more preferably 95% or more.

### [Method of Manufacturing Oxide Sputtering Target]

The oxide sputtering target according to this embodiment may be prepared, for example, in the following manner.

A MoO₂ raw material powder, a NbO₂ raw material powder, and a ZnO raw material powder are weighed and mixed to obtain the intended composition. It is preferable to use a raw material powder having a purity of 99.9% or higher, and an average particle diameter (D50) of 0.5 to 10 μm. As the mixing method, it is preferable to use a ball mill or the like and mix the raw material powders while simultaneously pulverizing the raw material powders. As the raw material powders, while it is possible to consider using a Nb₂O₅ powder and a Mo powder, because the sintering temperatures of Nb₂O₅ and Mo are considerably different, it is difficult to achieve high density.

Next, the mixed powder obtained by mixing the raw material powders is subject to hot press sintering (uniaxial pressure sintering) in an Ar atmosphere at a sintering temperature of 1100° C. or higher and 1200° C. or lower, pressing force of 250 MPa or more, and sintering time of 5 to 10 hours. It is thereby possible to obtain an oxide sintered body containing Mo, Nb, Zn, and O. Next, the obtained oxide sintered body is cut and polished and processed into a sputtering target, whereby the oxide sputtering target according to this embodiment can thereby be manufactured.

### [Method of Manufacturing Oxide Film]

The oxide thin film according to this embodiment may be prepared, for example, in the following manner.

By placing a NbO₂ sputtering target, a MoO₂ sputtering target, and a ZnO sputtering target, or a Nb—Mo—O sputtering target, in a sputtering device and performing simultaneous sputtering, a mixed film of NbO₂ and MoO₂ and ZnO can be deposited on a substrate. Here, the film composition can be changed by changing the sputtering power of each sputtering target during sputtering.

Otherwise, by placing the integrated sputtering target prepared based on the method described above in the sputtering device and performing sputtering, a mixed film of NbO₂ and MoO₂ and ZnO can also be deposited on a substrate. Here, the composition of the sputtering target will never be completely identical to the composition of the composition, but it is assumed that it will be an approximate composition. Because there is a relationship between the composition of the sputtering target and the composition of the film, it is possible to ascertain the composition of the sputtering target that can obtain the intended film composition by setting the conditions. Moreover, the amount of oxygen in the film can be adjusted by adjusting the flow rate of oxygen to be introduced during sputtering.

The deposition conditions of the oxide film may be set, for example, as follows.

### <Deposition Conditions>

Sputtering device: ANELVA SPL-500
Substrate temperature: Room temperature (no substrate heating)
Deposition atmosphere: Ar or Ar+O₂
Gas pressure: 0.2 to 2.0 Pa
Gas flow rate: 50 to 100 sccm
Power: 100 to 1000 W (DC, RF)
Substrate: Eagle XG manufactured by Corning (φ4 mm×0.7 mm)

### EXAMPLES

In the present disclosure, the various properties of the oxide film and the oxide sputtering target were measured under the following conditions.

### <Component Composition of Sputtering Target>

The component composition of the sputtering target was measured using the following device.
Device: SPS3500DD manufactured by SII
Method: ICP-OES (inductively coupled plasma optical emission spectrometry)

### <Reflectance and Transmittance of Oxide Film>

Device: Spectrophotometer UV-2600 manufactured by SHIMADZU
Light source: Deuterium lamp, halogen lamp
Measurement wavelength: 200 to 1400 nm
Measurement wavelength interval: 5 nm

### Measurement Sample:

(Reflectance) A sample (Cu laminated film) obtained by depositing copper having a film thickness of 100 nm on a glass substrate having a thickness of 0.7 mm, and thereafter depositing an oxide having a film thickness of 35 nm thereon, was used.

(Transmittance) A sample obtained by depositing an oxide having a film thickness of 35 nm on a glass substrate having a thickness of 0.7 mm was used.

### <Measurement Method>

(Reflectance) Relative total light reflectance using an integrating sphere (reference sample; polished mirror).

(Average reflectance) Reflectance was measured in 5 nm intervals in the wavelength region (400 to 700 nm), and the average value thereof was calculated.

(Transmittance) Relative transmittance against reference light.

(Average transmittance) Transmittance was measured in 5 nm intervals in the wavelength region (400 to 700 nm), and the average value thereof was calculated.

Note that, for both transmittance and reflectance, the measurement results when light was incident from the film side were used.

### <Amorphousness of Oxide Film>

The amorphousness of the oxide film was determined based on the presence of a diffraction peak of the oxide film (sample) based on X-ray diffraction. Measurement was performed under the following conditions, and the oxide film was determined to be an amorphous film when there was no diffraction peak caused by the oxide film. Note that the absence of a diffraction peak means that Iₘₐₓ/I_{BG}<5 when the maximum peak intensity at 2θ=10° to 60° is defined as Iₘₐₓ, and the average peak intensity at 2θ=20° to 25° is defined as I_{BG}. In the table, as the determination criteria of amorphousness, a case where Iₘₐₓ/I_{BG}<5 is satisfied is indicated as ∘, and a case where Iₘₐₓ/I_{BG}<5 is not satisfied is indicated as x.
Device: SmartLab manufactured by Rigaku
Tube: Cu—K α rays
Tube voltage: 40 kV
Current: 30 mA
Measurement method: 2θ-θ reflection method
Scanning speed: 20°/min
Sampling interval: 0.02°
Measurement range: 10° to 60°
Measurement sample: Sample (film thickness of 100 nm or more) on a glass substrate (Eagle XG)
Divergence slit: 1° Divergence vertical limit slit: 10 mm
Scattering slit: 8 mm
Receiving slit: Open state
Goniometer: Horizontal type

### <Film Thickness Measurement>

The film thickness of the oxide film was measured using a contact profiler (Dektak8 manufactured by Veeco). The film thickness of the oxide film was measured from the step between the deposited surface and the non-deposited surface of the glass substrate on which the oxide film was deposited.

### <Processability of Oxide Film by Etching>

A hydrogen peroxide (H₂O₂)-based chemical liquid (Pure Etch C200 manufactured by Hayashi Pure Chemical Industries) was used as the etching solution, the liquid temperature was set to 35° C., and an oxide film (sample) deposited on a substrate was immersed in the etching solution and etched for a predetermined period of time while agitating the etching solution. The sample was thereafter removed from the etching solution and the film thickness was measured, and the etching rate was calculated from the time required for the etching (immersion time), and the reduction in the film thickness of the oxide film (=(film thickness before etching)−(film thickness after etching)). It was determined that the etching processability is favorable when the etching rate was 1 nm/sec or higher.

### <Component Composition of Sputtering Target>

The composition of the sputtering target was measured using the following method and device.
Device: SPS3500DD manufactured by SII
Method: ICP-OES (inductively coupled plasma optical emission spectrometry)

### <Relative Density of Sputtering Target>

The dimensions (using a vernier caliper) and weight of the sintered body were measured to calculate the dimensional density, and from this dimensional density and the true density of the sintered body, the relative density (%)=dimensional density/true density×100 was calculated.

The true density was calculated from the compound ratio of each oxide and each theoretical density.
When the NbO₂ weight is defined as a (wt %), the MoO₂ weight is defined as b (wt %), and the ZnO weight is defined as c (wt %), the true density=100/(a/5.90+b/6.44+c/5.61)
Theoretical density of NbO₂: 5.90 g/cm³
Theoretical density of MoO₂: 6.44 g/cm³
Theoretical density of ZnO: 5.61 g/cm³

### <XRD Analysis of Sputtering Target>

The structure of the sputtering target was analyzed using the following device.
Device: SmartLab manufactured by Rigaku
Tube: Cu—K α rays
Tube voltage: 40 kV
Current: 30 mA
Measurement method: 2θ-θ reflection method
Scanning speed: 20°/min
Sampling interval: 0.02°
Measurement range: 10° to 60°
Sample measurement location: Sputtered surface
Divergence slit: 1° Divergence vertical limit slit: 10 mm
Scattering slit: 8 mm
Receiving slit: Open state
Goniometer: Horizontal type

The XRD peak intensity in the range of 25.5°≤2θ≤26.5°, which is attributable to the (102) plane of the Zn₂Mo₃O₈ phase, was defined as 12.

The XRD peak intensity in the range of 17.0°≤2θ≤17.5°, which is attributable to the (006) plane of the Zn₃Mo₃O₈ phase, was defined as I₃.

The average value of the XRD intensity in the range of 21.0°≤2θ≤22.0° was defined as background I₀.

### Example 1: Oxide Sputtering Target

A MoO₂ raw material powder, a NbO₂ raw material powder, and a ZnO raw material powder were weighed and mixed to obtain the intended composition. The obtained mixed powder was subject to hot press sintering (uniaxial pressure sintering) in an Ar atmosphere at a sintering temperature of 1100° C., pressing force of 250 MPa or more, and sintering time of 10 hours to prepare an oxide sintered body, and the obtained oxide sintered body was thereafter processed to prepare an oxide sputtering target. Composition analysis of the oxide sputtering target was performed, and the results were as follows.
Content ratio (atomic ratio) of Mo represented by Mo/(Mo+Nb+Zn) was 0.517
Content ratio (atomic ratio) of Nb represented by Nb/(Mo+Nb+Zn) was 0.248
Content ratio (atomic ratio) of Zn represented by Zn/(Mo+Nb+Zn) was 0.235

Moreover, the relative density of the oxide sputtering target was 96.5%, and the crystal phase was I₂/I₀=11.81, I₃/I₀=1.73.

### Example 2: Oxide Sputtering Target

A MoO₂ raw material powder, a NbO₂ raw material powder, and a ZnO raw material powder were weighed and mixed to obtain the intended composition. The obtained mixed powder was subject to hot press sintering (uniaxial pressure sintering) in an Ar atmosphere at a sintering temperature of 1075° C., pressing force of 250 MPa or more, and sintering time of 10 hours to prepare an oxide sintered body, and the obtained oxide sintered body was thereafter processed to prepare an oxide sputtering target. Composition analysis of the oxide sputtering target was performed, and the results were as follows.
Content ratio (atomic ratio) of Mo represented by Mo/(Mo+Nb+Zn) was 0.387
Content ratio (atomic ratio) of Nb represented by Nb/(Mo+Nb+Zn) was 0.185
Content ratio (atomic ratio) of Zn represented by Zn/(Mo+Nb+Zn) was 0.428

Moreover, the relative density of the oxide sputtering target was 99.9%, and the crystal phase was I₂/I₀=12.72, I₃/I₀=2.32.

### Comparative Example 1: Oxide Sputtering Target

A MoO₂ raw material powder, and a NbO₂ raw material powder were weighed and mixed to obtain the intended composition. Note that, in Comparative Example A-1, a ZnO powder was not included. The obtained mixed powder was subject to hot press sintering (uniaxial pressure sintering) in an Ar atmosphere at a sintering temperature of 1150° C., pressing force of 250 MPa or more, and sintering time of 10 hours to prepare an oxide sintered body, and the obtained oxide sintered body was thereafter processed to prepare an oxide sputtering target. Composition analysis of the oxide sputtering target was performed, and the results were as follows.
Content ratio (atomic ratio) of Mo represented by Mo/(Mo+Nb+Zn) was 0.90
Content ratio (atomic ratio) of Nb represented by Nb/(Mo+Nb+Zn) was 0.10

Moreover, the relative density of the oxide sputtering target was 93.1%.

### Comparative Example 2: Oxide Sputtering Target

A MoO₂ raw material powder, and a NbO₂ raw material powder were weighed and mixed to obtain the intended composition. Note that, in Comparative Example A-2, a ZnO powder was not included. The obtained mixed powder was subject to hot press sintering (uniaxial pressure sintering) in an Ar atmosphere at a sintering temperature of 1125° C., pressing force of 250 MPa or more, and sintering time of 10 hours to prepare an oxide sintered body, and the obtained oxide sintered body was thereafter processed to prepare an oxide sputtering target. Composition analysis of the oxide sputtering target was performed, and the results were as follows.
Content ratio (atomic ratio) of Mo represented by Mo/(Mo+Nb) was 0.81
Content ratio (atomic ratio) of Nb represented by Nb/(Mo+Nb) was 0.19

Moreover, the relative density of the oxide sputtering target was 89.4%.

### Comparative Example 3: Oxide Sputtering Target

A MoO₂ raw material powder, and a NbO₂ raw material powder were weighed and mixed to obtain the intended composition. Note that, in Comparative Example A-3, a ZnO powder was not included. The obtained mixed powder was subject to hot press sintering (uniaxial pressure sintering) in an Ar atmosphere at a sintering temperature of 1100° C., pressing force of 250 MPa or more, and sintering time of 10 hours to prepare an oxide sintered body, and the obtained oxide sintered body was thereafter processed to prepare an oxide sputtering target. Composition analysis of the oxide sputtering target was performed, and the results were as follows.
Content ratio (atomic ratio) of Mo represented by Mo/(Mo+Nb) was 0.713
Content ratio (atomic ratio) of Nb represented by Nb/(Mo+Nb) was 0.287

Moreover, the relative density of the oxide sputtering target was 87.1%.

### Comparative Example 4: Oxide Sputtering Target

A NbO₂ raw material powder, and a ZnO raw material powder were weighed and mixed to obtain the intended composition. Note that, in Comparative Example A-4, a MoO₂ powder was not included. The obtained mixed powder was subject to hot press sintering (uniaxial pressure sintering) in an Ar atmosphere at a sintering temperature of 1075° C., pressing force of 250 MPa or more, and sintering time of 10 hours to prepare an oxide sintered body, and the obtained oxide sintered body was thereafter processed to prepare an oxide sputtering target. Composition analysis of the oxide sputtering target was performed, and the results were as follows.
Content ratio (atomic ratio) of Mo represented by Nb/(Nb+Zn) was 0.382
Content ratio (atomic ratio) of Nb represented by Zn/(Nb+Zn) was 0.618

Moreover, the relative density of the oxide sputtering target was 95.8%.

The foregoing results are summarized in Table 1.

TABLE 1

| | Composition of sputtering target (at %) | | | Hot press | True | Dimensional | Relative | | |
|---|---|---|---|---|---|---|---|---|---|
| | Mo/(Mo + | Nb/(Mo + | Zn/(Mo + | maximum | density | density | density | | |
| | Nb + Zn) | Nb + Zn) | Nb + Zn) | temperature | (g/cm³) | (g/cm³) | (%) | I₂/I₀ | I₃/I₀ |
| Example 1 | 0.517 | 0.248 | 0.235 | 1100 | 6.41 | 5.95 | 96.5 | 11.81 | 1.73 |
| Example 2 | 0.387 | 0.185 | 0.428 | 1075 | 6.03 | 6.02 | 99.9 | 12.72 | 2.32 |
| Comparative | 0.900 | 0.100 | — | 1150 | 6.38 | 5.94 | 93.1 | N/A | N/A |
| Example 1 | | | | | | | | | |
| Comparative | 0.810 | 0.190 | — | 1125 | 6.33 | 5.66 | 89.4 | N/A | N/A |
| Example 2 | | | | | | | | | |
| Comparative | 0.713 | 0.287 | — | 1100 | 6.28 | 5.47 | 87.1 | N/A | N/A |
| Example 3 | | | | | | | | | |
| Comparative | — | 0.382 | 0.618 | 1075 | 5.98 | 5.73 | 95.8 | N/A | N/A |
| Example 4 | | | | | | | | | |

### Example 3: Oxide Film

Using the oxide sputtering target prepared in Example 1, sputtering was performed under the deposition conditions described above to deposit an oxide film having a film thickness of 35 nm on a glass substrate and a copper substrate, respectively. Analysis of the physical properties of the oxide film revealed that the etching rate was 1.50 nm/sec, the rate of change of transmittance was 13.0%, and the average reflectance was 7.60%. It was also confirmed that the oxide film is amorphous.

### Example 4: Oxide Film

Using the oxide sputtering target prepared in Example 2, sputtering was performed under the deposition conditions described above to deposit an oxide film having a film thickness of 35 nm on a glass substrate and a copper substrate, respectively. Analysis of the physical properties of the oxide film revealed that the etching rate was 1.52 nm/sec, the rate of change of transmittance was 6.5%, and the average reflectance was 10.60%. It was also confirmed that the oxide film is amorphous.

### Example 5: Oxide Film

Using the oxide sputtering target and the ZnO sputtering target prepared in Comparative Example 3, simultaneous sputtering was performed to deposit an oxide film having a film thickness of 35 nm on a glass substrate and a copper substrate, respectively. The composition of the oxide film was adjusted by controlling the deposition rate of each sputtering target as shown in Table 2. Analysis of the physical properties of the oxide film revealed that the etching rate was 1.15 nm/sec, the rate of change of transmittance was 14.4%, and the average reflectance was 6.9%. It was also confirmed that the oxide film is amorphous.

### Example 6: Oxide Film

Using the oxide sputtering target and the ZnO sputtering target prepared in Comparative Example 3, simultaneous sputtering was performed to deposit an oxide film having a film thickness of 35 nm on a glass substrate and a copper substrate, respectively. The composition of the oxide film was adjusted by controlling the deposition rate of each sputtering target as shown in Table 2. Analysis of the physical properties of the oxide film revealed that the etching rate was 1.45 nm/sec, the rate of change of transmittance was 13.7%, and the average reflectance was 7.8%. It was also confirmed that the oxide film is amorphous.

### Example 7: Oxide Film

Using the oxide sputtering target and the ZnO sputtering target prepared in Comparative Example 3, simultaneous sputtering was performed to deposit an oxide film having a film thickness of 35 nm on a glass substrate and a copper substrate, respectively. The composition of the oxide film was adjusted by controlling the deposition rate of each sputtering target as shown in Table 2. Analysis of the physical properties of the oxide film revealed that the etching rate was 1.48 nm/sec, the rate of change of transmittance was 7.2%, and the average reflectance was 10.9%. It was also confirmed that the oxide film is amorphous.

Here, Example 6 and Example 7 are oxide films deposited by simultaneous sputtering, and were each aimed at obtaining the same composition as the oxide films of Example 3 and Example 4 deposited using an integrated sputtering target, and therefore the physical properties of the oxides are approximate. Based on these results, it can be understood that the physical properties of the oxide film deposited using an integrated sputtering target can be reproduced by the oxide film deposited by simultaneous sputtering. In other words, it is possible to specify the composition range of the integrated sputtering target by taking into account the physical properties of the oxide film deposited by simultaneous sputtering.

### Example 8: Oxide Film

Using the oxide sputtering target and the ZnO sputtering target prepared in Comparative Example 3, simultaneous sputtering was performed to deposit an oxide film having a film thickness of 35 nm on a glass substrate and a copper substrate, respectively. Note that the composition of the oxide film was adjusted by controlling the deposition rate of each sputtering target as shown in Table 2. Analysis of the physical properties of the oxide film revealed that the etching rate was 3.10 nm/sec, the rate of change of transmittance was 6.5%, and the average reflectance was 13.9%. It was also confirmed that the oxide film is amorphous.

### Comparative Example 5

Using the oxide sputtering target prepared in Comparative Example 1, sputtering was performed under the deposition conditions described above to deposit an oxide film having a film thickness of 35 nm on a glass substrate and a copper substrate, respectively. Analysis of the physical properties of the oxide film revealed that the etching rate was 2.62 nm/sec, the rate of change of transmittance was 100.0%, and the average reflectance was 11.87%. It was also confirmed that the oxide film is amorphous.

### Comparative Example 6

Using the oxide sputtering target prepared in Comparative Example 2, sputtering was performed under the deposition conditions described above to deposit an oxide film having a film thickness of 35 nm on a glass substrate and a copper substrate, respectively. Analysis of the physical properties of the oxide film revealed that the etching rate was 1.89 nm/sec, the rate of change of transmittance was 75.5%, and the average reflectance was 6.57%. It was also confirmed that the oxide film is amorphous.

### Comparative Example 7

Using the oxide sputtering target prepared in Comparative Example 3, sputtering was performed under the deposition conditions described above to deposit an oxide film having a film thickness of 35 nm on a glass substrate and a copper substrate, respectively. Analysis of the physical properties of the oxide film revealed that the etching rate was 0.58 nm/sec, the rate of change of transmittance was 16.2%, and the average reflectance was 9.42%. It was also confirmed that the oxide film is amorphous.

### Comparative Example 8

Using the oxide sputtering target and the ZnO sputtering target prepared in Comparative Example 3, simultaneous sputtering was performed to deposit an oxide film having a film thickness of 35 nm on a glass substrate and a copper substrate, respectively. Note that the composition of the oxide film was adjusted by controlling the deposition rate of each sputtering target as shown in Table 2. Analysis of the physical properties of the oxide film revealed that the etching rate was 8.50 nm/sec, the rate of change of transmittance was 6.7%, and the average reflectance was 30.1%. It was also confirmed that the oxide film is amorphous.

The foregoing results are summarized in Table 2.

| | | | | | | | | | Rate of change | |
|---|---|---|---|---|---|---|---|---|---|---|
| | | | | | | | | | of transmittance | Cu laminated |
| | | | | | | | | | before and after | film |
| | | | Deposition rate | | | | | | constant- | reflectance |
| | | | (nm/sec) | | Target composition of oxide film | | | Etching | temperature, | (%) |
| | | | Comparative | | Mo/(Mo + | Nb/(Mo + | Zn/(Mo + | rate | constant- | (Ave. of |
| | Sputtering target | | Example 3 | ZnO | Nb + Zn) | Nb + Zn) | Nb + Zn) | (nm/sec) | humidity | 400~700 nm) |
| Example 3 | Example 1 | | N/A | N/A | 0 517 | 0.248 | 0.235 | 1.50 | 13.0 | 7.60 |
| Example 4 | Example 2 | | N/A | N/A | 0.387 | 0.185 | 0.428 | 1.52 | 6.5 | 10.60 |
| Example 5 | Comparative | ZnO | 0.445 | 0.049 | 0.618 | 0.248 | 0.134 | 1.15 | 14.4 | 6.9 |
| | Example 3 | | | | | | | | | |
| Example 6 | Comparative | ZnO | 0.464 | 0.082 | 0.517 | 0.248 | 0.235 | 1.45 | 13.7 | 7.8 |
| | Example 3 | | | | | | | | | |
| Example 7 | Comparative | ZnO | 0.393 | 0.168 | 0.387 | 0.185 | 0.428 | 1.48 | 7.2 | 10.9 |
| | Example 3 | | | | | | | | | |
| Example 8 | Comparative | ZnO | 0.371 | 0.247 | 0 370 | 0.149 | 0.482 | 3.10 | 6.5 | 13.9 |
| | Example 3 | | | | | | | | | |
| Comparative | Comparative | | N/A | N/A | 0.900 | 0.100 | — | 2.62 | 100.0 | 11.87 |
| Example 5 | Example 1 | | | | | | | | | |
| Comparative | Comparative | | N/A | N/A | 0.810 | 0.190 | — | 1.89 | 75.5 | 6.57 |
| Example 6 | Example 2 | | | | | | | | | |
| Comparative | Comparative | | N/A | N/A | 0.713 | 0.287 | — | 0.58 | 16.2 | 9.42 |
| Example 7 | Example 3 | | | | | | | | | |
| Comparative | Comparative | ZnO | 0.329 | 0.329 | 0.298 | 0.120 | 0.582 | 8.50 | 6.7 | 30.1 |
| Example 8 | Example 3 | | | | | | | | | |

### INDUSTRIAL APPLICABILITY

The oxide film according to this embodiment has favorable etching processability and excellent weatherability, and has a light absorption ability suitable for preventing the reflection of light. Moreover, the oxide sputtering target according to this embodiment is suitable for depositing the oxide film according to an embodiment of the present invention. The oxide film according to this embodiment is remarkably useful as a light absorbing film for preventing the reflection of light caused by metal wirings used in liquid crystal displays, plasma displays, organic EL displays, touch panels, solar cells, and the like, and also very useful as a photomask material, and for decorative purposes.

1: An oxide sputtering target containing molybdenum (Mo), niobium (Nb), zinc (Zn), and oxygen (O), wherein the oxide sputtering target includes a Zn₂Mo₃O₈ phase and/or a Zn₃Mo₃O₈ phase, and a content ratio (atomic ratio) of the Zn is
$$0.13 \leq Zn / ( Mo + Nb + Zn ) \leq 0.5 0 .$$

2: The oxide sputtering target according to claim 1, wherein a content ratio (atomic ratio) of the Mo is 0.30≤Mo/(Mo+Nb+Zn)≤0.70.

3: The oxide sputtering target according to claim 1, wherein a content ratio (atomic ratio) of the Nb is 0.15≤Nb/(Mo+Nb+Zn)≤0.30.

4: The oxide sputtering target according to claim 3, wherein a relative density is 90% or more.

5: An oxide film containing molybdenum (Mo), niobium (Nb), zinc (Zn), and oxygen (O), wherein an etching rate is 1 nm/sec or higher, an average reflectance against incident light in a visible light region (wavelength: 400 to 700 nm) is 15% or less, and a rate of change of an average transmittance in a visible light region (wavelength: 400 to 700 nm) before and after a constant-temperature, constant-humidity test is within 15%.

6: The oxide film according to claim 5, wherein the oxide film contains molybdenum (Mo), niobium (Nb), zinc (Zn), and oxygen (O), and a content ratio (atomic ratio) of the Zn is 0.13≤Zn/(Mo+Nb+Zn)≤0.50.

7: The oxide film according to claim 5, wherein a content ratio (atomic ratio) of the Mo is 0.30≤Mo/(Mo+Nb+Zn)≤0.70.

8: The oxide film according to claim 5, wherein a content ratio (atomic ratio) of the Nb is 0.15≤Nb/(Mo+Nb+Zn)≤0.30.

9: The oxide film according to claim 8, wherein the oxide film has a film thickness of 15 nm or more and 1000 nm or less.

10: The oxide film according to claim 8, wherein the oxide film is amorphous.

11: The oxide film according to claim 7, wherein the oxide film has a film thickness of 15 nm or more and 1000 nm or less.

12: The oxide film according to claim 7, wherein the oxide film is amorphous.

13: The oxide film according to claim 6, wherein the oxide film has a film thickness of 15 nm or more and 1000 nm or less.

14: The oxide film according to claim 6, wherein the oxide film is amorphous.

15: The oxide film according to claim 5, wherein the oxide film has a film thickness of 15 nm or more and 1000 nm or less.

16: The oxide film according to claim 5, wherein the oxide film is amorphous.

17: The oxide sputtering target according to claim 2, wherein a relative density is 90% or more.

18: The oxide sputtering target according to claim 1, wherein a relative density is 90% or more.
